(19) United States
(12) Patent Application Publication
(10) Pub. No.: US 2025/0280615 A1
(43) Pub. Date: Sep. 4, 2025

(54) IMAGE SENSOR AND METHOD OF FORMING THE SAME

(71) Applicant: VisEra Technologies Company Ltd., Hsin-Chu City (TW)

(72) Inventors: Po-Han FU, Hsin-Chu City (TW); Chin-Chuan HSIEH, Hsin-Chu City (TW)

(21) Appl. No.: 18/592,934

(22) Filed: Mar. 1, 2024

(51) Int. Cl. H01L 27/146; G02B 1/00

(52) U.S. Cl. CPC H10F 39/806; H10F 39/024; H10F 39/182; H10F 39/8053; G02B 1/002

(57) ABSTRACT

The image device includes a plurality of photodiodes, a color filter layer, and a metasurface layer. The color filter layer is over the plurality of photodiodes, wherein the color filter layer includes a blue filter, a red filter, a first green filter, and a second green filter. The metasurface layer is over the color filter layer and includes a first pixel unit, wherein the first pixel unit includes a blue region above the blue filter, a red region above the red filter, a first green region above the first green filter, and a second green region above the second green filter. The first green region includes a first central nanopost offset from a center of the first green region by a first longitudinal shift on a Y-axis direction and a first horizontal shift on a X-axis direction of the first central nanopost from a top view.

### BACKGROUND

### Field of Invention

The present disclosure relates to an image device and a method of forming the image device.

### Description of Related Art

In a complementary metal oxide semiconductor (CMOS) image sensor (also referred to as a CIS), a receiving component, such as a micro-lens layer or a metasurface layer, may have the function of receiving and separating an incident light including different wavelengths with different colors. A color filter layer may be disposed below the receiving component and acts as an absorber to absorb the light with a specific wavelength band before the light propagates into photodiodes. The color routing of the light in the image device further affect the performance of the image device.

However, the pattern of color filters in the color filter layer and the design of the metasurface layer, such as the arrangement and shapes of nanostructures in the metasurface layer, may have an impact on the color routing of the light. Therefore, there is a need to design the metasurface layer to increase the performance of the image device.

### SUMMARY

One aspect of the present disclosure is to provide an image device. The image device includes a plurality of photodiodes, a color filter layer, and a metasurface layer. The color filter layer is over the plurality of photodiodes, wherein the color filter layer includes a blue filter, a red filter, a first green filter, and a second green filter. The metasurface layer is over the color filter layer and includes a first pixel unit, wherein the first pixel unit includes a blue region above the blue filter, a red region above the red filter, a first green region above the first green filter, and a second green region above the second green filter. The first green region includes a first central nanopost offset from a center of the first green region by a first longitudinal shift on a Y-axis direction and a first horizontal shift on a X-axis direction of the first central nanopost from a top view. The second green region includes a second central nanopost offset from a center of the second green region by a second longitudinal shift on the Y-axis direction and a second horizontal shift on the X-axis direction of the second central nanopost from the top view.

In some embodiments, the first longitudinal shift and the first horizontal shift are determined according to an incidence angle and an azimuthal angle of the first green region. The incidence angle of the first green region is between a first incident light on an upper surface of the first green region and a normal line of the upper surface of the first green region. The azimuthal angle of the first green region is between a horizontal axis of the metasurface layer that passes through a center of the metasurface layer and a first connection line between the center of the first green region and the center of the metasurface layer.

In some embodiments, the metasurface layer further includes a second pixel unit, wherein the second pixel unit includes a third green region, the third green region includes a third central nanopost offset from a center of the third green region by a third longitudinal shift on the Y-axis direction and a third horizontal shift on the X-axis direction of the third central nanopost from the top view, wherein the third longitudinal shift and the third horizontal shift are determined according to an incidence angle and an azimuthal angle of the third green region. The incidence angle of the third green region is between a second incident light on an upper surface of the third green region and a normal line of the upper surface of the third green region. The azimuthal angle of the third green region is between the horizontal axis of the metasurface layer that passes through the center of the metasurface layer and a second connection line between the center of the third green region and the center of the metasurface layer. The first longitudinal shift of the first central nanopost and the third longitudinal shift of the third central nanopost satisfy the following equation:

$${D}_{GR} ( θ , ∅ ) = {D}_{GR} ( {θ}_{i} , {∅}_{j} ) + Δθ \frac{\partial {D}_{GR}}{\partial θ} + Δ∅ \frac{\partial {D}_{GR}}{\partial ∅}$$

wherein θ is the incidence angle of the first green region and θ is not equal to 0 degrees, Ø is the azimuthal angle of the first green region, D_{GR}(θ,Ø) is the first longitudinal shift of the first central nanopost, θᵢ is the incidence angle of the third green region and θᵢ is not equal to 0 degrees, Øⱼ is the azimuthal angle of the third green region, D_{GR}(θᵢ,Øⱼ) is the third longitudinal shift of the third central nanopost, Δθ is a first difference between the incidence angle of the first green region and the incidence angle of the third green region, ΔØ is a second difference between the azimuthal angle of the first green region and the azimuthal angle of the third green region.

In some embodiments, the first horizontal shift of the first central nanopost and the third horizontal shift of the third central nanopost satisfy the following equation:

$${D}_{GB} ( θ , ∅ ) = {D}_{GB} ( {θ}_{i} , {∅}_{j} ) + Δθ \frac{\partial {D}_{GB}}{\partial θ} + Δ∅ \frac{\partial {D}_{GB}}{\partial ∅}$$

wherein D_{GB}(θ,Ø) is the first horizontal shift of the first central nanopost, and D_{GB}(θᵢ,Øⱼ) is the third horizontal shift of the third central nanopost.

In some embodiments, an edge of the first green region is offset from a corresponding edge of the first green filter by an offset distance of the first green region, the color filter layer comprises a third green filter adjacent to the first green filter, the third green region is above the third green filter, and an edge of the third green region is offset from a corresponding edge of the third green filter by an offset distance of the third green region. the offset distance of the first green region and the offset distance of the third green region satisfy the following equation:

$$S ( θ ) = S ( {θ}_{i} ) + Δθ \frac{dS}{d θ}$$

wherein S(θ) is the offset distance of the first green region, and S(θᵢ) is the offset distance of the third green region.

In some embodiments, the offset distance of the first green region is in a range from 0 to 300 nm, θ is greater than 0 degrees and ≤ 35 degrees, and Ø is in a range from 0 to 360 degrees.

In some embodiments, the metasurface layer further comprises a plurality of peripheral nanoposts, and the peripheral nanoposts are located at corners of the blue region, the red region, the first green region, and the second green region.

In some embodiments, the first longitudinal shift of the first central nanopost is within ⅕ of a dimension of the first green filter, and the first horizontal shift of the first central nanopost is within ⅕ of the dimension of the first green filter.

In some embodiments, the first longitudinal shift and the first horizontal shift include positive shifts. The second longitudinal shift and the second horizontal shift comprise positive shifts. The positive shift of the first longitudinal shift is defined by a shift from the first green region toward the red region, and the positive shift of the first horizontal shift is defined by a shift from the first green region toward the blue region. The positive shift of the second longitudinal shift is defined by a shift from the second green region toward the blue region, and the positive shift of the second horizontal shift is defined by a shift from the second green region toward the red region.

In some embodiments, the first longitudinal shift and the first horizontal shift include negative shifts. The second longitudinal shift and the second horizontal shift comprise negative shifts. The negative shift of the first longitudinal shift is defined by a shift from the first green region away from the red region, and the negative shift of the first horizontal shift is defined by a shift from the first green region away from the blue region. The negative shift of the second longitudinal shift is defined by a shift from the second green region away from the blue region, and the negative shift of the second horizontal shift is defined by a shift from the second green region away from the red region.

In some embodiments, the metasurface layer further comprises a filling material, the filling material laterally encloses the first central nanopost and the second central nanopost, wherein a refractive index of the filling material is in a range from 1.0 to 1.6.

In some embodiments, the image device further comprises a dielectric layer, and the dielectric layer is disposed between the color filter layer and the blue filter, the red filter, the first green filter, and the second green filter.

In some embodiments, a dimension of each of the blue region, the red region, the first green region, and the second green region is in a range from 400 nm to 700 nm. A refractive index of the first central nanopost is in a range from 1.8 to 3.5.

One aspect of the present disclosure is to provide a method of forming an image device. The method includes the following steps. A plurality of photodiodes is provided. A color filter layer is formed over the plurality of photodiodes, wherein the color filter layer includes a blue filter, a red filter, a first green filter, and a second green filter. A metasurface layer is formed over the color filter layer, wherein the metasurface layer includes a first pixel unit, wherein the first pixel unit comprises a blue region above the blue filter, a red region above the red filter, a first green region above the first green filter, and a second green region above the second green filter, wherein the first green region includes a first central nanopost, the second green region includes a second central nanopost. Forming the metasurface layer includes the following steps: forming the first central nanopost offset from a center of the first green region by a first longitudinal shift on a Y-axis direction and a first horizontal shift on a X-axis direction of the first central nanopost from a top view; and forming the second central nanopost offset from a center of the second green region by a second longitudinal shift on the Y-axis direction and a second horizontal shift on the X-axis direction of the second central nanopost from the top view.

In some embodiments, the first longitudinal shift and the first horizontal shift are determined according to an incidence angle and an azimuthal angle of the first green region. The incidence angle of the first green region is between a first incident light on an upper surface of the first green region and a normal line of the upper surface of the first green region. The azimuthal angle of the first green region is between a horizontal axis of the metasurface layer that passes through a center of the metasurface layer and a first connection line between the center of the first green region and the center of the metasurface layer.

In some embodiments, forming the metasurface layer further includes forming a plurality of peripheral nanoposts at corners of the blue region, the red region, the first green region, and the second green region.

In some embodiments, forming the metasurface layer further includes forming a filling material laterally enclosing the peripheral nanoposts, the first central nanopost, and the second central nanopost.

In some embodiments, the method of forming the image device further includes forming a dielectric layer disposed between the color filter layer and the blue filter, the red filter, the first green filter, and the second green filter.

In some embodiments, the first longitudinal shift and the first horizontal shift include positive shifts. The second longitudinal shift and the second horizontal shift comprise positive shifts. The positive shift of the first longitudinal shift is defined by a shift from the first green region toward the red region, and the positive shift of the first horizontal shift is defined by a shift from the first green region toward the blue region. The positive shift of the second longitudinal shift is defined by a shift from the second green region toward the blue region, and the positive shift of the second horizontal shift is defined by a shift from the second green region toward the red region.

In some embodiments, the first longitudinal shift and the first horizontal shift include negative shifts. The second longitudinal shift and the second horizontal shift comprise negative shifts. The negative shift of the first longitudinal shift is defined by a shift from the first green region away from the red region, and the negative shift of the first horizontal shift is defined by a shift from the first green region away from the blue region. The negative shift of the second longitudinal shift is defined by a shift from the second green region away from the blue region, and the negative shift of the second horizontal shift is defined by a shift from the second green region away from the red region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an image device when an incident light does not occur in normal incidence in accordance with some embodiments of the present disclosure.

FIG. 2 is a side view of a portion of the image device in FIG. 1.

FIG. 3 is a top view of a metasurface layer in FIG. 1.

FIG. 4A is a top view of a layout for a metasurface layer when an incident light occurs in normal incidence in accordance with some embodiments of the present disclosure.

FIG. 4B is a top view of a layout for the metasurface layer in FIG. 1.

FIG. 5A is a coordinate illustrating the definitions of different parameters when an incident light occurs in normal incidence.

FIG. 5B to FIG. 5D are coordinates illustrating the definitions of different parameters when an incident light does not occur in normal incidence.

FIG. 5E is an array of a metasurface layer in accordance with some embodiments of the present disclosure.

FIG. 5F is a schematic diagram of reference points.

FIG. 6A is a side view of a portion of an image device under an incidence angle (θᵢ) of a third green region in accordance with some embodiments of the present disclosure.

FIG. 6B is a side view of a portion of an image device under an incidence angle (θ) of a first green region in accordance with some embodiments of the present disclosure.

FIG. 7 is a top view of a metasurface layer in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed.

It will be understood that, although the terms “first,” “second,” etc. may be used herein to describe various elements, these elements should not be limited by these terms. These terms are only used to distinguish one element from another. For example, a “first element” may be termed a “second element,” and, similarly, a “second element” may be termed a “first element,” without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean ±20% of the stated value, more typically ±10% of the stated value, more typically ±5% of the stated value, more typically ±3% of the stated value, more typically ±2% of the stated value, more typically ±1% of the stated value and even more typically ±0.5% of the stated value. The stated value of the present disclosure is an approximate value.

In response to the continually reduced pixel size, a light reception of each pixel (which may be defined by different color filters) and a light reception uniformity between different pixels have become matters of critical concern. If the light receptions between different pixels are imbalanced, an image device would experience color variations and cause an insufficient amount of quantum efficiencies (QE) between different pixels, thereby decreasing the performance of the image device. In addition, an incidence angle of an incident light would also have an impact on the quantum efficiencies of the image device.

Hereinafter, several embodiments of the present invention will be disclosed with the accompanying drawings. Many practical details will be described in the following description for a clear description. However, it should be understood that these practical details should not be used to limit the present invention. That is, in some embodiments of the present invention, these practical details are unnecessary. In addition, in order to simplify the drawings, some conventional structures and elements will be shown in the drawings in a simple schematic manner.

Since the incident light is a combination of different wavelengths with different colors and photodiodes in the image device are used for detecting the incident light, there is a need to separate the incident light through a metasurface layer and a color filter layer before transmitting the light to the photodiodes. The metasurface consists of a plurality of nanostructures (such as nanoposts or pillars) that form specific phase distributions, which provides the required phase distributions for different wavelengths. The metasurface guides different incident wavelengths to their own target positions, which is also known as color routing. The target positions herein represent different color filters in the color filter layer.

For example, after the phase distributions of the incident wavelengths are adjusted, a specific phase distribution transmits to a red color filter allowing the red light, and then the red light transmitted to the photodiode(s) below the red color filter, so that an electrical signal of the red light may be detected. In this case, the specific phase distribution for the red color filter may be understood as used for the red light.

The image device of the present disclosure considers that different incidence angles of incident light in a CMOS array would affect the quantum efficiencies of different green pixels in a Bayer pattern. The positions of the nanoposts in the metasurface layer of the present disclosure may be adjusted by the disclosed equations, which are calculated according to the incidence angles of the incident light and the azimuthal angle of the nanoposts. The disclosed metasurface layer can provide similar amounts of quantum efficiencies between different green pixels in the Bayer pattern, thereby avoiding the occurrence of channel separation of different green pixels and increasing the performance of the image device. The channel separation herein indicates that the quantum efficiencies of photodiodes in different green pixels are imbalanced.

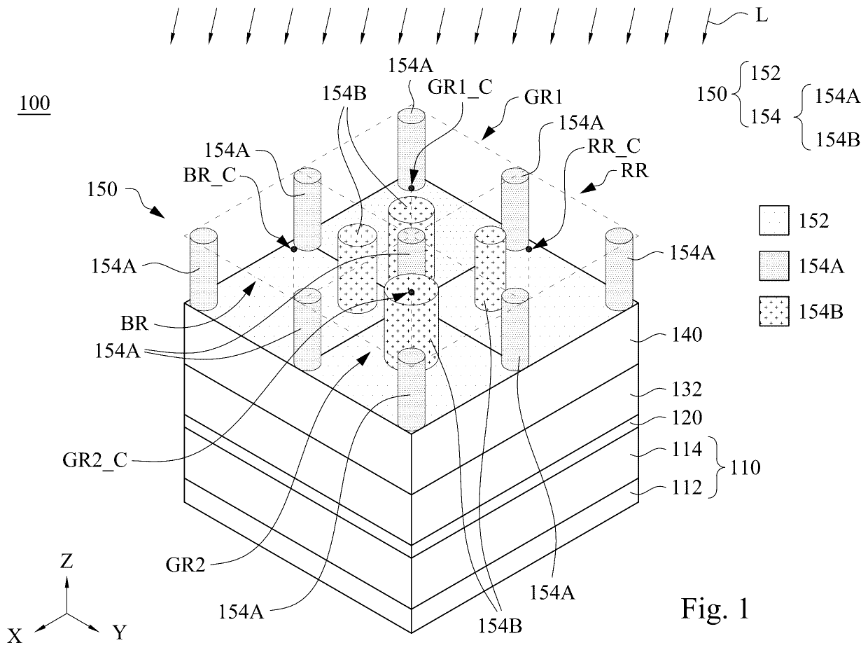

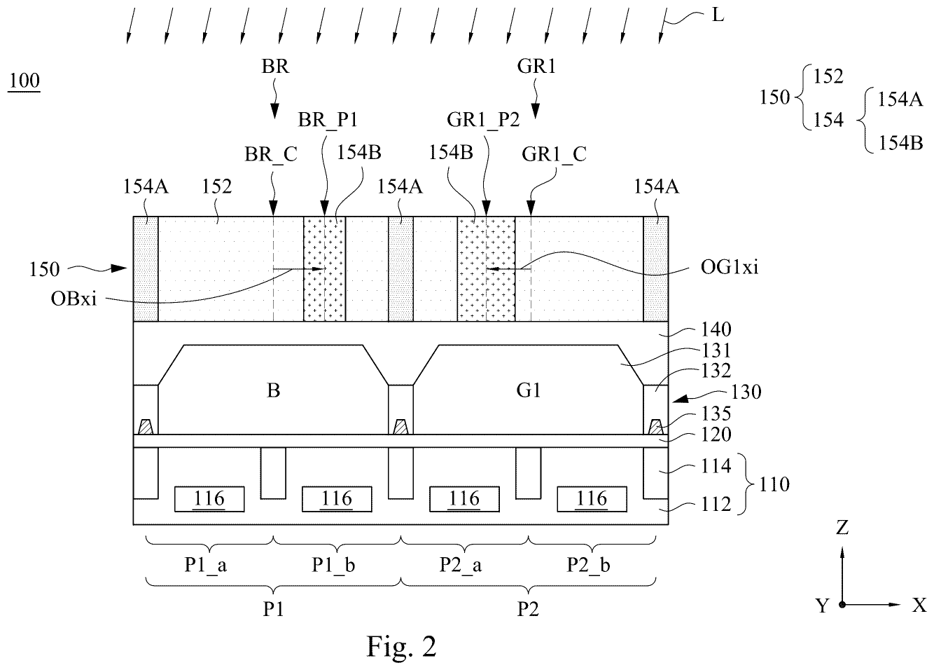

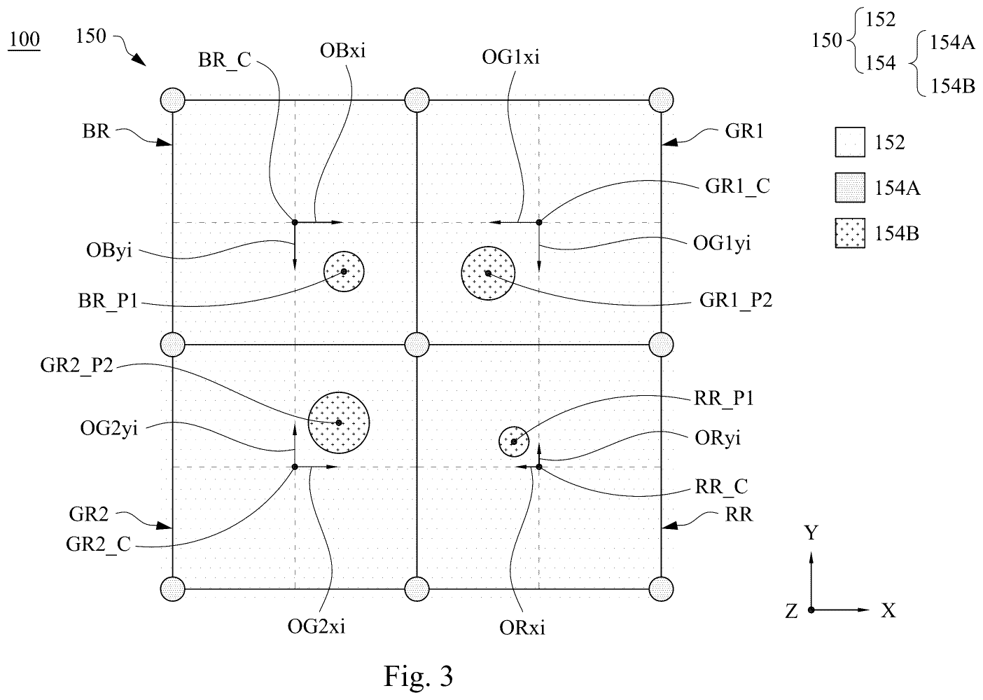

FIG. 1 is a perspective view of an image device 100 when an incident light L does not occur in normal incidence in accordance with some embodiments of the present disclosure. In other words, the incident light L in FIG. 1 is oblique with respect to an upper surface of a metasurface layer 150. FIG. 2 is a side view of a portion of the image device 100 in FIG. 1. Specifically, FIG. 2 merely illustrates a half portion (such as a blue region BR and a first green region GR1, and underlying components thereof) of the image device 100 in FIG. 1. FIG. 3 is a top view of a metasurface layer in FIG. 1.

In FIG. 1 and FIG. 2, the image device 100 includes a photoelectric conversion layer 110. The photoelectric conversion layer 110 includes a substrate 112, a plurality of deep trench isolations (DTIs) 114, and a plurality of photodiodes 116.

As shown in FIG. 2, the DTIs 114 and the photodiodes 116 are embedded in the substrate 112, and each of the photodiodes 116 is disposed between two DTIs 114. In some embodiments, the substrate 112 may be a single structure shared by all of the DTIs 114 and the photodiodes 116 of the image device 100. The DTIs 114 are configured to avoid light interference between adjacent photodiodes 116. The photodiodes 116 are configured to sense the incident light L and generate intensity signals according to the intensity of the incident light L propagating thereon. The intensity signals form the image signals.

In some embodiments, the substrate 112 may be a semiconductor substrate, an organic photoelectric conversion substrate, a semiconductor on insulator (SOI) substrate, or another suitable substrate. In other embodiments, transistors, photodiodes, or the like, may be formed at the active regions (which are defined by the DTIs 114) of the substrate 112. In some embodiments, additional isolation structures may be applied as an alternative, such as shallow trench isolations (STIs) and local oxidation of silicon (LOCOS) structures. In some embodiments, the DTIs 114 may be formed by a photolithography process.

In FIG. 1 and FIG. 2, the image device 100 includes an anti-reflection layer 120 disposed on the substrate 112. The anti-reflection layer 120 is configured to decrease the reflection of the light being transmitted to the underlying photodiodes 116. In some embodiments, the anti-reflection layer 120 may be formed by a material including silicon oxynitride (SiOₓN_{y}, wherein x and y are in the range from 0 to 1).

In FIG. 1 and FIG. 2, the image device 100 includes a color filter layer 130 disposed on the anti-reflection layer 120. The color filter layer 130 includes a plurality of color filters, for example, a blue filter B, a first green filter G1, a second green filter G2, and a red filter R. The color filter layer 130 is arranged in a 2×2 array, which is visible in a top view. In some embodiments, the color filter layer 130 is arranged according to a Bayer pattern. As shown in FIG. 2, the color filter layer 130 further includes a plurality of grid structures 132 and a plurality of light shielding structures 135. The grid structures 132 are disposed adjacent to the color filters. For example, as shown in FIG. 2, the grid structures 132 are disposed adjacent to the blue filter B and the first green filter G1. The grid structures 132 are configured to isolate the light within the specific unit to serve as the light-trapping function. Each of the light shielding structures 135 is embedded within one of the grid structures 132. The light shielding structures 135 are configured to prevent the underlying photodiodes 116 from receiving additional light from different colored lights in the adjacent components.

In some embodiments, each filter (such as the blue filter B, the first green filter G1, the second green filter G2, and the red filter R) of the color filter layer 130 allows a predetermined range of wavelengths of light to pass therethrough. For example, the red filter R allows wavelengths of light in a range from about 620 nm to about 750 nm (red light) to transmit to the corresponding photodiodes 116, the first green filter G1 and the second green filter G2 allow wavelengths of light in a range from about 495 nm to about 570 nm (green light) to transmit to the corresponding photodiodes 116, and the blue filter B allow wavelengths of light in a range about from 450 nm to about 495 nm (blue light) to transmit to the corresponding photodiodes 116. The first green filter G1 may be the same as the second green filter G2.

In some embodiments, a height of the color filter layer 130 is in a range from about 0.3 μm to about 2.0 μm, such as 0.5, 0.9, 1.2, 1.5, or 1.8 μm. In some embodiments, a height of the grid structure 132 may be higher than or equal to a height of the light shielding structure 135, depending on the design requirements of the image device 100. In some embodiments, the height of the light shielding structure 135 is in a range from about 0.005 μm to about 2.000 μm. In some embodiments, the grid structures 132 may be formed by a material including a transparent dielectric material. In some embodiments, the light shielding structures 135 may be formed by a material including opaque metals such as tungsten (W), aluminum (AI)), opaque metal nitride, opaque metal oxide, other suitable materials, or combinations thereof.

In the present disclosure, one “pixel” is determined by one color filter, and each pixel may correspond to at least one photodiode. Specifically, in the cross-sectional view of FIG. 2, a pixel P1 is determined by the blue filter B of the color filter layer 130 and the pixel P1 corresponds to two photodiodes 116. The photodiodes 116 under the blue filter B is arranged in a 2×2 array (such as quad photodiodes (DPD)). In the case that the photodiodes 116 are arranged in the 2×2 array, the blue filter B corresponds to four photodiodes 116 As shown in FIG. 2, the pixel P1 includes a left pixel P1_a and a right pixel P1_b, in which each of the left pixel P1_a and the right pixel P1_b corresponds to one photodiode 116.

Similarly, in the cross-sectional view of FIG. 2, a pixel P2 is determined by the first green filter G1 of the color filter layer 130 and the pixel P2 corresponds to two photodiodes 116. The photodiodes 116 under the first green filter G1 is arranged in a 2×2 array. As shown in FIG. 2, the pixel P2 includes a left pixel P2_a and a right pixel P2_b, in which each of the left pixel P2_a and the right pixel P2_b corresponds to one photodiode 116. It may be understood that each of the DTIs 114 may serve as a boundary of the left pixel P1_a, the right pixel P1_b, the left pixel P2_a, or the right pixel P2_b. Each of the grid structures 132 may serve as a boundary of a different pixel (such as the pixel P1 or the pixel P2). Each center line (not shown) of the grid structure 132 may define the borders of different pixels. In other words, the grid structure 132 in the middle of FIG. 2 spans across the border of the pixel P1 and the pixel P2. In some embodiments, a dimension of each of the pixel P1 or the pixel P2 is in a range from about 400 nm to about 700 nm, such as 500 or 600 nm.

It should be understood that, in each of the pixel (such as the pixel P1 or the pixel P2), the photodiodes 116 may be arranged in an m×n array, in which m and n are positive integers that can be the same or different, but the present disclosure is not limited thereto. For example, the photodiodes 116 under the blue filter B may be arranged in a 1×2 array (such as dual photodiodes (DPD)), and the photodiodes 116 under the first green filter G1 may be arranged in a 1×2 array. In the case that the photodiodes 116 are arranged in the 1×2 array, the blue filter B corresponds to two photodiodes 116 and the first green filter G1 also corresponds to two photodiodes 116.

In FIG. 1 and FIG. 2, the image device 100 includes a dielectric layer 140 (also referred to as a spacer layer) disposed on the color filter layer 130. As shown in FIG. 2, the dielectric layer 140 covers and the top portions 131 of the color filter layer 130 (such as the blue filter B and the first green filter G1) and the grid structures 132. In the embodiment of the image device 100, the dielectric layer 140 may provide the necessary travel path for the incident light L of different diffractions to reach their respective targets (different color filters in the color filter layer 130). In some embodiments, the top portion 131 of each color filter in the color filter layer 130 has a trapezoidal shape, with its upper surface smaller than its lower surface.

In some embodiments, a thickness of the dielectric layer 140 is in a range from about 0.1 μm to about 0.5 μm, such as 0.2, 0.3, or 0.4 μm. The dimension of the dielectric layer 140 may be adjusted depending on the design requirements of the image device 100. In some embodiments, the dielectric layer 140 may be formed by a material including silicon oxide, silicon nitride, silicon carbide, silicon (SiCN), silicon oxynitride, silicon oxynitrocarbide, tetraethyl orthosilicate (TEOS), low-k dielectric material, or other suitable material.

In FIG. 1 and FIG. 2, the image device 100 includes a metasurface layer 150 disposed on the dielectric layer 140. In other words, the metasurface layer 150 is disposed over the color filter layer 130. As shown in FIG. 1 to FIG. 3, the metasurface layer 150 has a blue region BR, a first green region GR1, a second green region GR2, and a red region RR, and these regions are arranged in a 2×2 array. Specifically, the blue region BR is above the underlying blue filter B, the first green region GR1 is above the underlying first green filter G1, the second green region GR2 is above the underlying second green filter G2, and the red region RR is above the underlying red filter R. In some embodiments, a dimension of each of the blue region BR, the first green region GR1, the second green region GR2, and the red region RR is in a range from about 400 nm to about 700 nm. In some embodiments, a height of the metasurface layer is in a range from about 0.7 μm to about 1.5 μm, such as 1.2 μm.

In FIG. 1 to FIG. 3, the metasurface layer 150 includes a filling material 152 and a plurality of nanostructures 154. The filling material 152 laterally encloses the nanostructures 154. The nanostructures 154 include a plurality of peripheral nanoposts 154A and a plurality of central nanoposts 154B. Specifically, the peripheral nanoposts 154A are located at corners of each of the blue region BR, the first green region GR1, the second green region GR2, and the red region RR. In each of the blue region BR, the first green region GR1, the second green region GR2, and the red region RR, one of the central nanoposts 154B is surrounded by the plurality of peripheral nanoposts 154A.

As shown in FIG. 2, the peripheral nanopost 154A in the middle of FIG. 2 spans across the borders of the blue region BR and the first green region GR1, and the central nanoposts 154B do not share adjacent colored regions. Each of the peripheral nanoposts 154A aligns with each of the grid structures 132, for example, a center line of the peripheral nanopost 154A aligns with a center line of the grid structure 132. In order to more clearly illustrate the configuration of the nanostructures 154, the medium of the filling material 152 in FIG. 1 is illustrated in dash lines.

In the embodiments of the image device 100, the nanostructures 154 are cylinder columns. In some embodiments, the central nanopost 154B and the peripheral nanopost 154A have a round, rectangular, or triangular profile in a top view. In some alternative embodiments, in each of the blue region BR, the first green region GR1, the second green region GR2, and the red region RR, a plurality of middle nanoposts (not shown) may be disposed between the central nanopost 154B and the peripheral nanoposts 154A. In some embodiments, the middle nanoposts are arranged in a cycle and the central nanopost 154B is located in a cylindrical configuration.

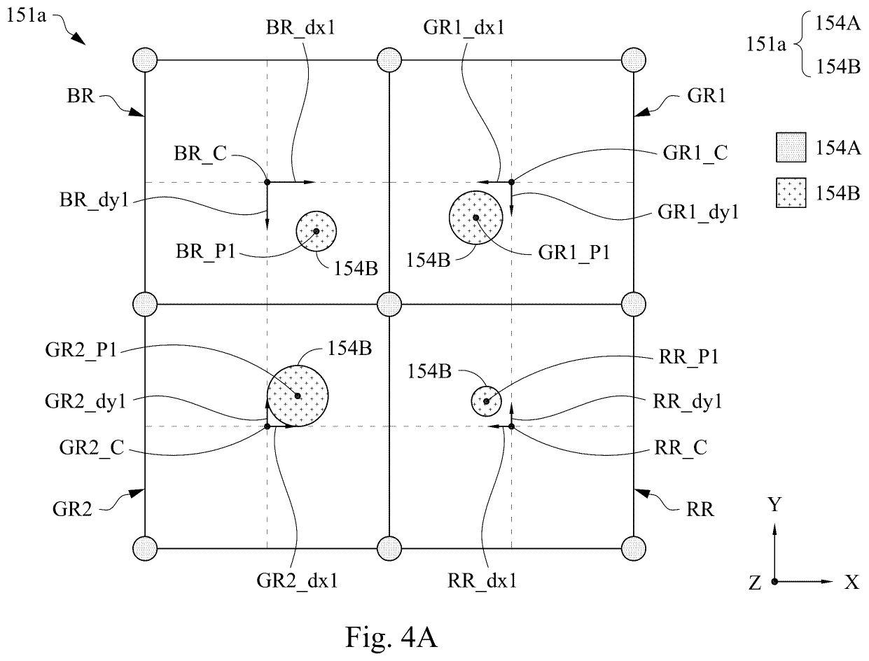

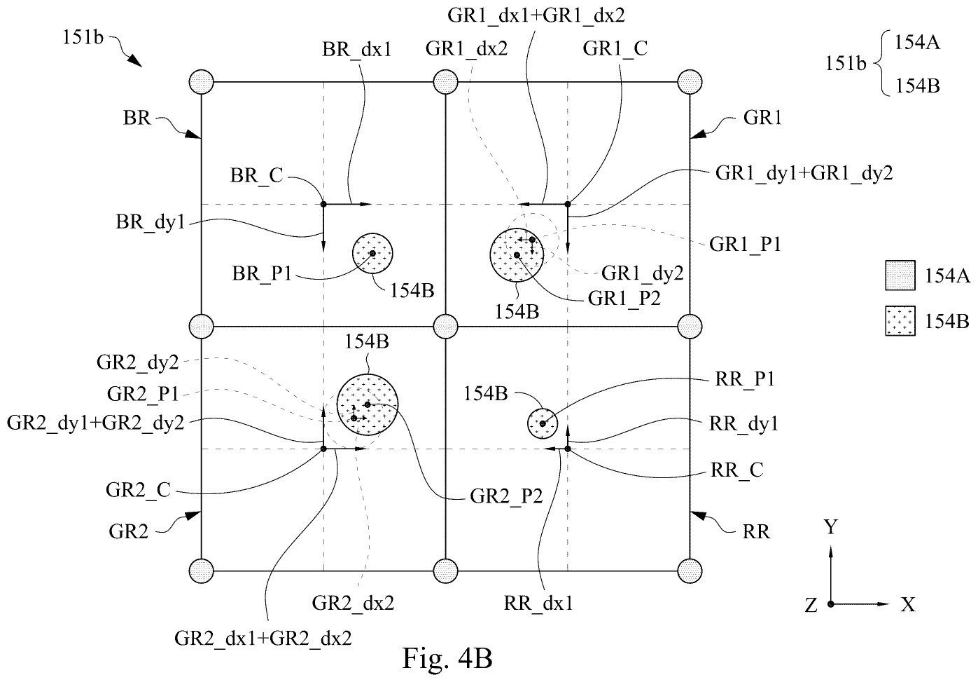

Reference is made to FIG. 2 and FIG. 3. The central nanopost 154B in the blue region BR has an offset amount OBxi and OByi relative to the center point BR_C of the blue region BR. The central nanopost 154B in the first green region GR1 has an offset amount OG1xi and OG1yi relative to the center point GR1_C of the first green region GR1. The central nanopost 154B in the second green region GR2 has an offset amount OG2xi and OG2yi relative to the center point GR2_C of the second green region GR2. The central nanopost 154B in the red region RR has an offset amount ORxi and ORyi relative to the center point RR_C of the red region RR. The offset amounts OBxi, OG1xi, OG2xi, and ORxi represent the offset amounts in the direction X when the incidence angle of the incident light L is oblique with respect to the upper surface of the metasurface layer 150. The offset amounts OByi, OG1yi, OG2yi, and ORyi represent the offset amounts in the direction Y when the incidence angle of the incident light L is oblique with respect to the upper surface of the metasurface layer 150. In some embodiments, the offset amounts OBxi, OG1xi, OG2xi, and ORxi and the offset amounts OByi, OG1yi, OG2yi, and ORyi mentioned above may be within ⅕ of the dimension of the pixel P1 (referring to FIG. 2). The layout of the nanostructures 154 will be discussed in detail in FIG. 4B below.

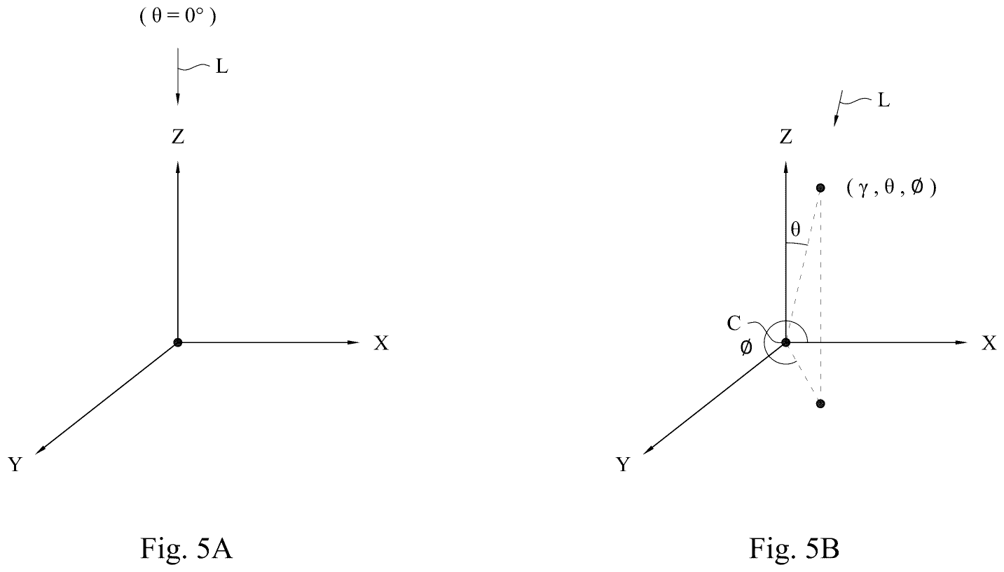

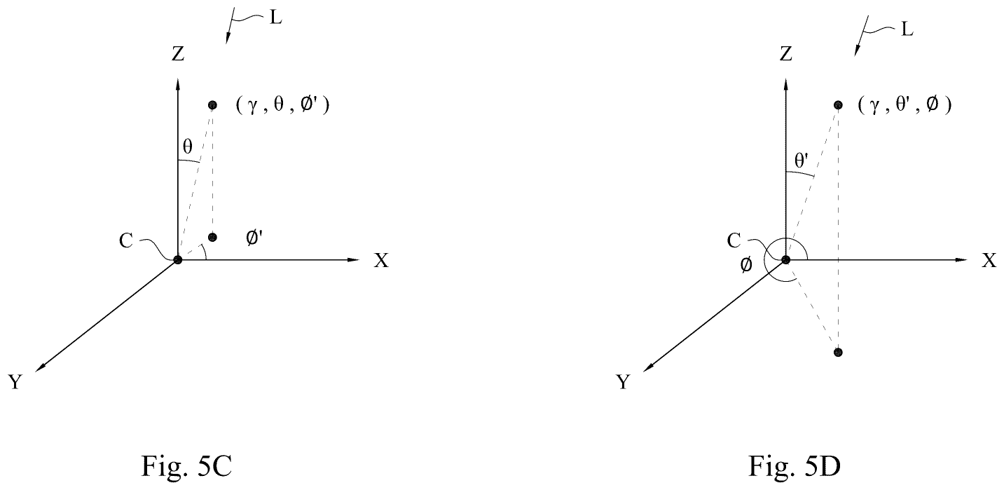

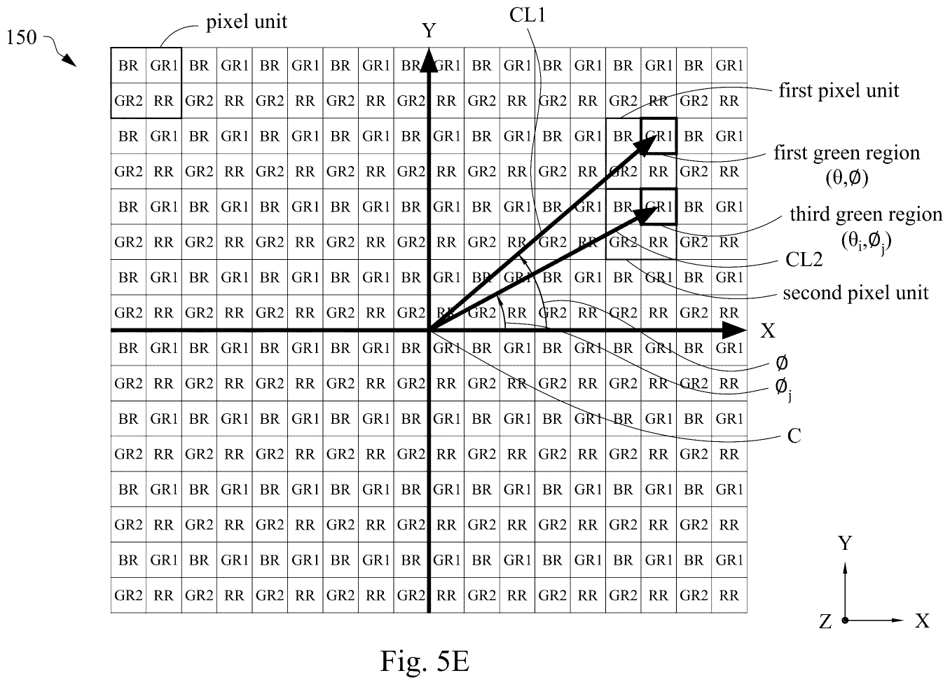

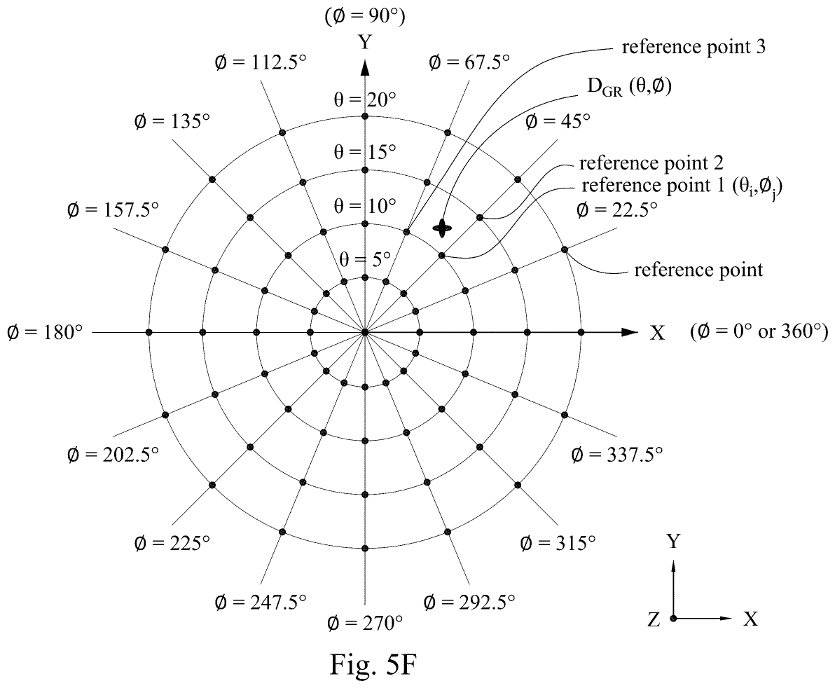

FIG. 4A is a top view of a layout 151a for a metasurface layer when an incident light L occurs in normal incidence in accordance with some embodiments of the present disclosure. FIG. 5A is a coordinate illustrating the definitions of different parameters when the incident light L occurs in normal incidence. “Normal incidence” herein refers to the incidence angle of the incident light L being parallel to the direction Z.

In the three-dimensional coordinates of FIG. 5A, θ is the incidence angle of the incident light L. It is understood that the incidence angle θ is equal to 0 degrees when the incidence angle of the incident light L is perpendicular to a XY-plane, and the layout 151a shown in FIG. 4A is the condition that the incident light L is in normal incidence. In other words, a normal vector of the XY-plane is parallel to the incidence angle of the incident light L when the incidence angle θ is equal to 0.

FIG. 4B is a top view of a layout 151b for the metasurface layer 150 in FIG. 1. FIG. 5B to FIG. 5D are coordinates illustrating the definitions of different parameters when an incident light L does not occur in normal incidence. It should be understood that the condition differences between FIG. 4A and FIG. 4B are the incidence angles of the incident light L, so that the layouts 151a and 151b are different. Specifically, the metasurface layer in FIG. 4A is on the condition that the incident light L is in normal incidence, and the metasurface layer in FIG. 4B is on the condition that the incident light L is not in normal incidence.

When the incident light L is not in normal incidence (that is, the incidence angle of the incident light L is oblique with respect to the upper surface of the metasurface layer 150), the offset amounts of the central nanoposts 154B in the first green region GR1 and the second green region GR2 have additional offset amounts compared to that in the layout 151a of FIG. 4A. Referring to FIG. 4A and FIG. 4B, the layout differences between FIG. 4A and FIG. 4B are the positions of the central nanopost 154B in the first green region GR1 and the central nanopost 154B in the second green region GR2.

Reference is made to FIG. 4A. In the blue region BR, the central nanopost 154B offsets from the center point BR_C by an offset distance to locate at an offset position BR_P1, in which the offset distance is defined by a horizontal shift BR_dx1 on a X-axis direction and a longitudinal shift BR_dy1 on a Y-axis direction. In the first green region GR1, the central nanopost 154B offsets from the center point GR1_C by an offset distance to locate at an offset position GR1_P1, in which the offset distance is defined by a horizontal shift GR1_dx1 on the X-axis direction and a longitudinal shift GR1_dy1 on the Y-axis direction. In the second green region GR2, the central nanopost 154B offsets from the center point GR2_C by an offset distance to locate at an offset position GR2_P1, in which the offset distance is defined by a horizontal shift GR2_dx1 on the X-axis direction and a longitudinal shift GR2_dy1 on the Y-axis direction. In the red region RR, the central nanopost 154B offsets from the center point RR_C by an offset distance to locate at an offset position RR_P1, in which the offset distance is defined by a horizontal shift RR_dx1 on the X-axis direction and a longitudinal shift RR_dy1 on the Y-axis direction. It may be understood that the “horizontal shift” in the present disclosure represents a shift on a direction parallel to the X-axis, and the “longitudinal shift” in the present disclosure represents a shift on a direction parallel to the Y-axis. In some embodiments, the horizontal shifts and the longitudinal shifts mentioned above may be within ⅕ of the dimension of the pixel P1 (referring to FIG. 2).

Please refer to FIG. 4B. In the first green region GR1, the central nanopost 154B offsets from the offset position GR1_P1 by an additional offset distance to locate at an offset position GR1_P2, in which the additional offset distance is defined by a horizontal shift GR1_dx2 on the X-axis direction and a longitudinal shift GR1_dy2 on the Y-axis direction. In the second green region GR2, the central nanopost 154B offsets from the offset position GR2_P1 by an additional offset distance to locate at an offset position GR2_P2, in which the additional offset distance is defined by a horizontal shift GR2_dx2 on the X-axis direction and a longitudinal shift GR2_dy2 on the Y-axis direction.

It should be understood that the horizontal shift BR_dx1 and the longitudinal shift BR_dy1 shown in FIG. 4B respectively are equal to the offset amounts OBxi and OByi shown in FIG. 3. The horizontal shift GR1_dx1 plus the horizontal shift GR1_dx2 shown in FIG. 4B are equal to the offset amount OG1xi shown in FIG. 3, and the longitudinal shift GR1_dyl plus the longitudinal shift GR1_dy2 are equal to the offset amount OG1yi shown in FIG. 3. The horizontal shift GR2_dx1 plus the horizontal shift GR2_dx2 shown in FIG. 4B are equal to the offset amount OG2xi shown in FIG. 3, and the longitudinal shift GR2_dy1 plus the longitudinal shift GR2_dy2 are equal to the offset amount OG2yi shown in FIG. 3. The horizontal shift RR_dx1 and the longitudinal shift RR_dy1 shown in FIG. 4B respectively are equal to the offset amounts ORxi and ORyi shown in FIG. 3.

In the embodiment of FIG. 4B, the horizontal shift GR1_dx2 in the first green region GR1 is the same as the horizontal shift GR2_dx2 in the second green region GR2, and the longitudinal shift GR1_dy2 in the first green region GR1 is the same as the longitudinal shift GR2_dy2 in the second green region GR2.

Please refer to FIG. 5B to FIG. 5D. θ is the incidence angle of the incident light L and Ø is the azimuthal angle. In the case that the incident light L is oblique with respect to the upper surface of the metasurface layer 150 (referring to FIG. 3), the incidence angle θ of the incident light L would no longer to be 0. Therefore, incidence angle θ may be defined by an included angle between the incidence direction of the incident light L and the normal vector of the XY-plane coordinate. The azimuthal angle corresponds to the included angle on the XY-plane coordinate.

Please refer to the equations mentioned below, both D_{GR} and D_{GB} are functions of the incidence angle θ and the azimuthal angle Ø. The incidence angle θ and azimuthal angle Ø can refer to FIG. 5B to FIG. 5D.

As shown in FIG. 5B and FIG. 5C, the position (r, θ, Ø) and the position (r, θ, Ø′) have the same incidence angles but different azimuthal angles, in which θ is not greater than 35 degrees and Ø is between 0 and 360 degrees, and Ø>Ø′. As shown in FIG. 5B and FIG. 5D, the position (r, θ, Ø) and the position (r, θ′, Ø) have the same azimuthal angles but different incidence angles, in which θ is not greater than 35 degrees and Ø is between 0 and 360 degrees, and θ′>θ. All the conditions that the incident light L does not occur in normal incidence can be calculated by the equations mentioned below. D_{GR}(θ,Ø) and D_{GB}(θ,Ø) would vary depending on the incidence angle of incident light L and the azimuthal angle.

FIG. 5E is an array of the metasurface layer 150 in accordance with some embodiments of the present disclosure. “Pixel unit” herein is composed of one blue region BR, one first green region GR1, one second green region GR2, and one red region RR. The metasurface layer 150 is composed of a plurality of pixel units, as shown in FIG. 5E. FIG. 5E illustrates a first pixel unit and a second pixel unit adjacent to the first pixel unit. It is understood that there includes one central nanopost 154B in each of the blue region BR, the first green region GR1, the second green region GR2, and the red region RR in each of the first pixel unit and the second pixel unit.

Referring to FIG. 4B and FIG. 5E, the horizontal shift GR1_dx1 plus the horizontal shift GR1_dx2 in the first green region GR1 is determined according to the incidence angle θ and the azimuthal angle Ø of the first green region GR1, and the longitudinal shift GR1_dy1 plus the longitudinal shift GR1_dy2 in the first green region GR1 is also determined according to the incidence angle θ and the azimuthal angle Ø of the first green region GR1. The incidence angle θ of the first green region GR1 is between a first incident light L (referring to FIG. 1 and FIG. 5B) on an upper surface of the first green region GR1 and a normal line of the upper surface of the first green region GR1. Referring to FIG. 5E, the azimuthal angle Ø of the first green region GR1 is between a horizontal axis X of the metasurface layer 150 that passes through a center C of the metasurface layer 150 and a first connection line CL1 between the center of the first green region GR1 and the center C of the metasurface layer 150.

As shown in FIG. 5E, the metasurface layer 150 further includes a second pixel unit, wherein the second pixel unit includes a third green region, the third green region includes a third central nanopost offset from a center of the third green region by a third longitudinal shift and a third horizontal shift of the third central nanopost, wherein the third longitudinal shift and the third horizontal shift are determined according to an incidence angle (θᵢ) and an azimuthal angle (Øⱼ) of the third green region. The incidence angle (θᵢ) of the third green region is between a second incident light on an upper surface of the third green region and a normal line of the upper surface of the third green region. The azimuthal angle (Øⱼ) of the third green region is between the horizontal axis X of the metasurface layer that passes through the center C of the metasurface layer 150 and a second connection line CL2 between the center of the third green region and the center C of the metasurface layer 150. The longitudinal shift GR1_dy1 plus the longitudinal shift GR1_dy2 (referring to FIG. 4B) of the central nanopost 154B in the first green region GR1 and the third longitudinal shift of the third central nanopost satisfy the following equation:

$${D}_{GR} ( θ , ∅ ) = {D}_{GR} ( {θ}_{i} , {∅}_{j} ) + Δθ \frac{\partial {D}_{GR}}{\partial θ} + Δ∅ \frac{\partial {D}_{GR}}{\partial ∅}$$

wherein θ is the incidence angle of the first green region and θ is not equal to 0 degrees, Ø is the azimuthal angle of the first green region, D_{GR}(θ,Ø) is the longitudinal shift GR1_dy1 plus the longitudinal shift GR1_dy2 of the first central nanopost, θᵢ is the incidence angle of the third green region and θᵢ is not equal to 0 degrees, Øⱼ is the azimuthal angle of the third green region, D_{GR}(θᵢ,Øⱼ) is the third longitudinal shift of the third central nanopost, Δθ is a first difference between the incidence angle of the first green region and the incidence angle of the third green region, Δθ is a second difference between the azimuthal angle of the first green region and the azimuthal angle of the third green region.

FIG. 5F is a schematic diagram of reference points. Reference point 1 and reference point 2 represent known DGR(θᵢ,Øⱼ) above, and reference point 3 represents unknown D_{GR}(θ,Ø) above. Reference point 3 can be obtained by the nearest reference points (such as reference point 1 or reference point 2).

The horizontal shift GR1_dx1 plus the horizontal shift GR1_dx2 (referring to FIG. 4B) of the first central nanopost 154B in the first green region GR1 and the third horizontal shift of the third central nanopost satisfy the following equation:

$${D}_{GB} ( θ , ∅ ) = {D}_{GB} ( {θ}_{i} , {∅}_{j} ) + Δθ \frac{\partial {D}_{GB}}{\partial θ} + Δ∅ \frac{\partial {D}_{GB}}{\partial ∅}$$

wherein D_{GB}(θ,Ø) is the horizontal shift GR1_dx1 plus the horizontal shift GR1_dx2 of the first central nanopost, and D_{GB}(θᵢ,Øⱼ) is the third horizontal shift of the third central nanopost.

In some embodiments, θ is greater than 0 degrees and ≤35 degrees, and Ø is in a range from 0 to 360 degrees.

After the layout 151b of FIG. 4B is obtained, the nanostructures 154 (including the peripheral nanoposts 154A and the central nanoposts 154B) are formed according to the layout 151b, as shown in FIG. 3. In some embodiments, the nanostructures 154 may be formed by any suitable deposition process and patterning process, and then the filling material 152 is formed to laterally enclose the peripheral nanoposts 154A and the central nanoposts 154B. In an alternative embodiment, the peripheral nanoposts 154A and the central nanoposts 154B are formed by depositing the filling material 152, followed by etching multiple holes within the filling material 152. In other words, the nanostructures 154 may be holes, which are filled with ambient air, and then the material of the nanostructures 154 are formed into the holes.

In FIG. 1 to FIG. 3, in some embodiments, the dimensions (such as the diameters) of the nanostructures 154 in a top view is in a range from about 120 nm to about 250 nm. The dimensions of the central nanoposts 154B may be equal to or greater than the dimensions of the peripheral nanoposts 154A. Even though the nanostructures 154 are illustrated as circular shapes in a top view, the present disclosure is not limited thereto. The nanostructures 154 may have any suitable geometrical shape, as long as the necessary phase distribution of different colored lights may be formed.

In some embodiments, the nanostructures 154 may be formed by a material including transparent conductive materials, such as indium tin oxide (ITO), tin oxide (SnO), indium zinc oxide (IZO), indium gallium zinc oxide (IGZO), indium tin zinc oxide (ITZO), antimony tin oxide (ATO), aluminum-doped zinc oxide (AZO), titanium dioxide (TiO₂), other suitable material, or combinations thereof. In some embodiments, the filling material 152 may be formed by transparent resins, such as polyethylene terephthalate (PET) resins, polycarbonate (PC) resins, polyimide (PI) resins, polymethylmethacrylates (PMMA), polystyrene resins, other suitable resins, or combinations thereof.

In the above-mentioned equations, each of D_{GR} and D_{GB} includes a positive shift and a negative shift. The positive shift of D_{GR} is defined by a shift from the green region (such as the first green region GR1 or the second green region GR2) toward the red region RR, and the positive shift of D_{GB} is defined by a shift from the green region (such as the first green region GR1 or the second green region GR2) toward the blue region BR. Specifically, in the first green region GR1 of FIG. 4B, both the longitudinal shift GR1_dy1 and the longitudinal shift GR1_dy2 can be understood as the “positive shifts” of D_{GR}, and both the horizontal shift GR1_dx1 and the horizontal shift GR1_dx2 can be understood as the “positive shifts” of D_{GB}. In the second green region GR2 of FIG. 4B, both the horizontal shift GR2_dx1 and the horizontal shift GR2_dx2 can be understood as the “positive shifts” of D_{GR}, and both the longitudinal shift GR2_dy1 and the longitudinal shift GR2_dy2 can be understood as the “positive shifts” of D_{GB}.

In the embodiment of FIG. 3, all of the horizontal shift GR1_dx1, the horizontal shift GR1_dx2, the longitudinal shift GR1_dyl, and the longitudinal shift GR1_dy2 in the first green region GR1 are positive shifts. Similarly, all of the horizontal shift GR2_dx1, the horizontal shift GR2_dx2, the longitudinal shift GR2_dyl, and the longitudinal shift GR2_dy2 in the second green region GR2 are positive shifts.

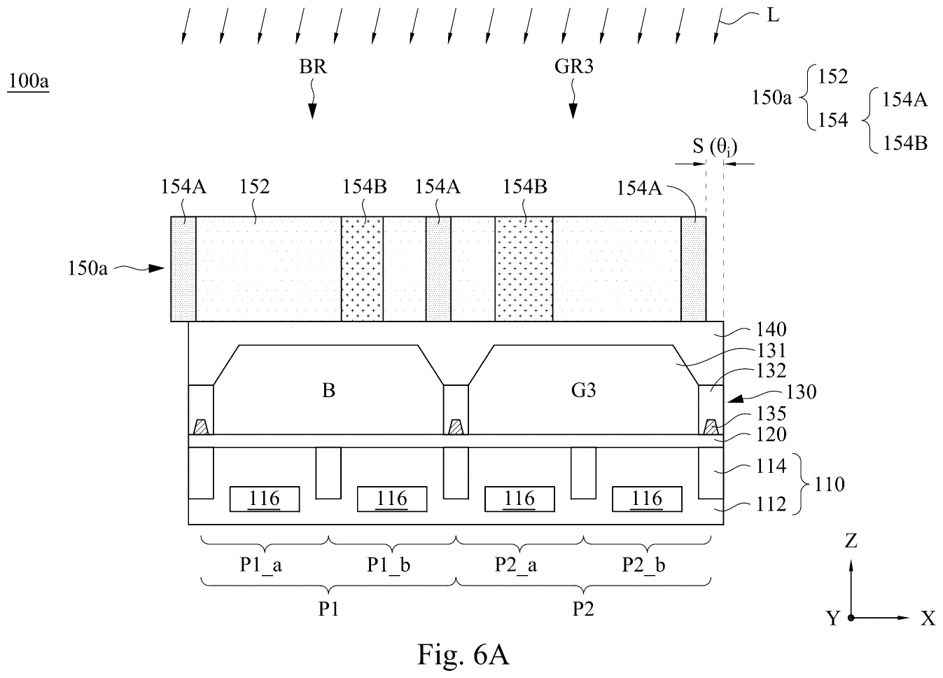

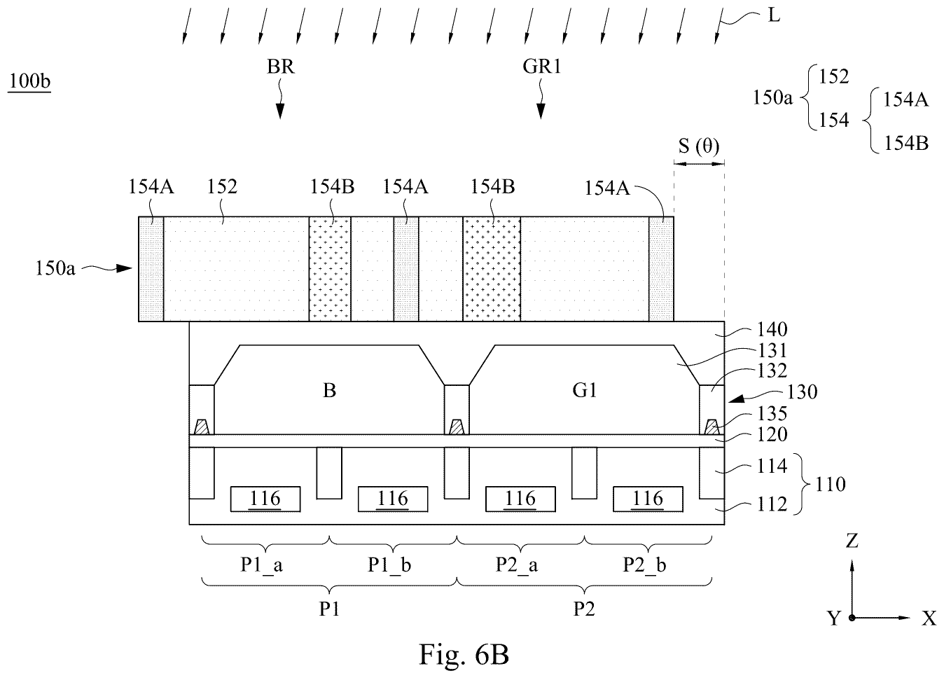

FIG. 6A is a side view of a portion of an image device 100a under an incidence angle θᵢ of the third green region GR3 in accordance with some embodiments of the present disclosure. FIG. 6B is a side view of a portion of an image device 100b under an incidence angle θ of the first green region GR1 in accordance with some embodiments of the present disclosure.

As shown in FIG. 6B, an edge of the first green region GR1 is offset from a corresponding edge of the first green filter G1 by an offset distance of the first green region GR1. The color filter 130 includes a third green filter G3 (referring to FIG. 6A) adjacent to the first green filter G1 (referring to FIG. 6B). The third green region GR3 is above the third green filter G3, and an edge of the third green region GR3 is offset from a corresponding edge of the third green filter G3 by an offset distance of the third green region GR3, as shown in FIG. 6A. The offset distance of the first green region GR1 and the offset distance of the third green region GR3 satisfy the following equation:

$$S ( θ ) = S ( {θ}_{i} ) + Δθ \frac{dS}{d θ}$$

wherein S(θ) is the offset distance of the first green region GR1, and S(θᵢ) is the offset distance of the third green region GR3. In some embodiments, the offset distance of the first green region GR1 is in a range from 0 to 300 nm.

In some embodiments, the offset distance S(θ) is in a range from about −P½ to about P½. In some embodiments, the offset distance S(θ) is 0 nm when θ is 0 degree. In some embodiments, the offset distance S(θ) is 72 nm when θ is 7.5 degrees. In some embodiments, the offset distance S(θ) is 157 nm when θ is 15 degrees. In some embodiments, the offset distance S(θ) is 209 nm when θ is 22.5 degrees. In some embodiments, the offset distance S(θ) is 291 nm when θ is 30 degrees.

A method of forming the image device 100 includes the following steps. The photoelectric conversion layer 110 is formed. The anti-reflection layer 120 is formed on the photoelectric conversion layer 110. The color filter layer 130 is formed on the anti-reflection layer 120. The dielectric layer 140 is formed on the color filter layer 130. The metasurface layer 150 (including the peripheral nanoposts 154A and the central nanoposts 154B) is formed on the dielectric layer 140, in which the metasurface layer 150 is formed according to the layout 151b.

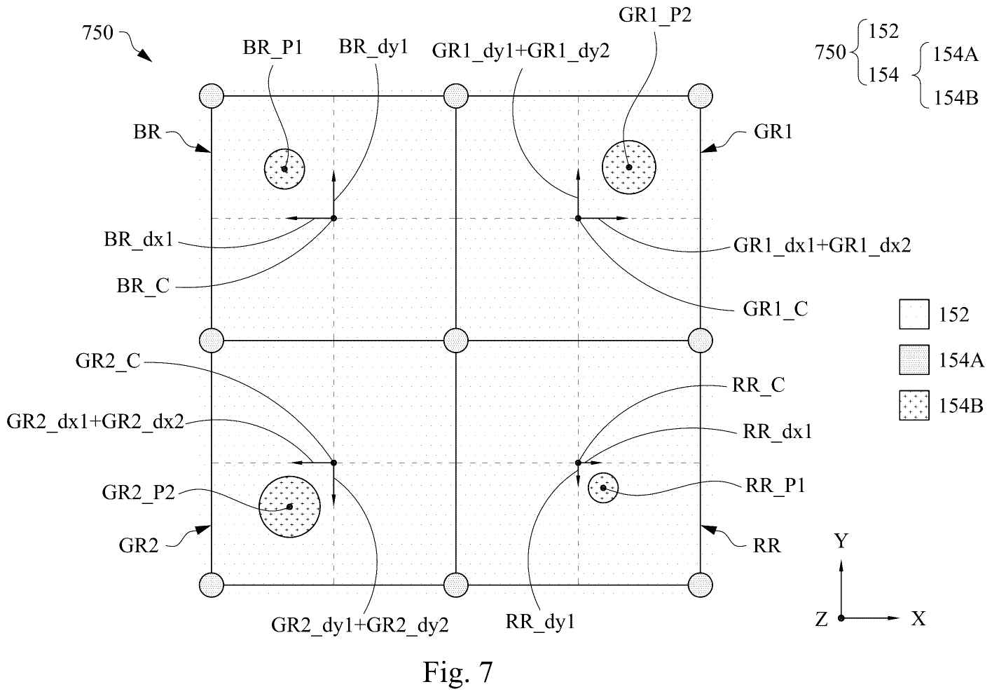

FIG. 7 is a top view of a metasurface layer 750 in accordance with some embodiments of the present disclosure. The differences between the metasurface layer 750 in FIG. 7 and the metasurface layer 150 in FIG. 3 are the positions of the central nanoposts 154B in the blue region BR, the first green region GR1, the second green region GR2, and the red region RR, respectively. The central nanoposts 154B in FIG. 7 have negative shifts. In the present disclosure, the negative shift of D_{GR} is defined by a shift from the green region (such as the first green region GR1 or the second green region GR2) away from the red region RR, and the negative shift of D_{GB} is defined by a shift from the green region (such as the first green region GR1 or the second green region GR2) away from the blue region BR. Specifically, in the first green region GR1 of FIG. 7, both the longitudinal shift GR1_dy1 and the longitudinal shift GR1_dy2 can be understood as the “negative shifts” of D_{GR}, and both the horizontal shift GR1_dx1 and the horizontal shift GR1_dx2 can be understood as the “negative shifts” of D_{GB}. In the second green region GR2 of FIG. 7, both the horizontal shift GR2_dx1 and the horizontal shift GR2_dx2 can be understood as the “negative shifts” of D_{GR}, and both the longitudinal shift GR2_dy1 and the longitudinal shift GR2_dy2 can be understood as the “negative shifts” of D_{GB}.

In the embodiment of FIG. 7, all of the horizontal shift GR1_dx1, the horizontal shift GR1_dx2, the longitudinal shift GR1_dy1, and the longitudinal shift GR1_dy2 in the first green region GR1 are negative shifts. Similarly, all of the horizontal shift GR2_dx1, the horizontal shift GR2_dx2, the longitudinal shift GR2_dy1, and the longitudinal shift GR2_dy2 in the second green region GR2 are negative shifts.

Reference is made to the image device 100 in FIG. 2. In some embodiments, a refractive index of the nanostructures 154 (including the peripheral nanoposts 154A and the central nanoposts 154B) is greater than a refractive index of the filling material 152. In some embodiments, the refractive index of the peripheral nanoposts 154A is the same as the refractive index of the central nanopost 154B. In some embodiments, the refractive index of the peripheral nanoposts 154A is in a range from about 1.8 to about 3.5, such as 2.0, 2.5, or 3.0. In some embodiments, the refractive index of the central nanopost 154B is in a range from about 1.8 to about 3.5, such as 2.0, 2.5, or 3.0. In some embodiments, the refractive index of the filling material 152 is in a range from about 1.0 to about 1.6, such as 1.2 or 1.4. In some embodiments, the filling material 152 may be air. It is worth noting that, when the nanostructures 154 are enclosed by ambient air (the refractive index of the filling material 152 is 1), the largest difference between the refractive indices may be realized to generate a significantly broader phase distribution, so the incident light L may be more easily separated based on the different wavelengths. In some embodiments, a radius of the central nanopost 154B in each of the blue region BR, the first green region GR1, the second green region GR2, and the red region RR are different from each other. The dimensions of each of the central nanoposts 154B may be adjusted depending on the design requirements of the image device 100.

Reference is made to the image device 100 in FIG. 2 again. In some embodiments, a refractive index of the dielectric layer 140 is less than the refractive indices of the nanostructures 154. In some embodiments, the refractive index of the dielectric layer 140 is in a range from about 1.0 to about 1.6, such as 1.2 or 1.4. In some embodiments, the refractive index of each filter (such as the blue filter B, the first green filter G1, the second green filter G2, and the red filter R) of the color filter layer 130 is greater than the refractive index of the grid structures 132. In some embodiments, the refractive index of each filter of the color filter layer 130 is in a range from about 1.4 to about 2.3, such as 1.6, 1.8, 2.0, or 2.2. In some embodiments, a refractive index of the grid structures 132 is in a range from about 1.0 to about 1.3, such as 1.1 or 1.2.

The present disclosure takes the condition that the incident light L does not occur in normal incidence into account and provides a method for forming the metasurface layer, in which the central nanopost(s) in the green region(s) have additional offset distance(s) comparing to the central nanoposts in the blue region and the red region. The additional offset distance(s) may be calculated by the equations mentioned above. The metasurface layer of the present disclosure allows a wide range of incidence angle of the incident light and provides balanced amounts quantum efficiencies for different green pixels in the Bayer pattern. The disclosed metasurface layer can provide similar amounts of quantum efficiencies between different green pixels, thereby avoiding the occurrence of channel separation of different green pixels and increasing the performance of the image device.

The present disclosure has been disclosed as hereinabove, however, it is not used to limit the present disclosure. Those skilled in the art may make various changes, substitutions, and alterations herein without departing from the spirit and scope of the present disclosure. Therefore, the scope of protection of the present disclosure shall be subject to the scope of the claim attached in the application and its equivalent constructions.

1. An image device, comprising:
a plurality of photodiodes;
a color filter layer over the plurality of photodiodes, wherein the color filter layer comprises a blue filter, a red filter, a first green filter, and a second green filter; and
a metasurface layer over the color filter layer and comprising a first pixel unit, wherein the first pixel unit comprises a blue region above the blue filter, a red region above the red filter, a first green region above the first green filter, and a second green region above the second green filter,
wherein the first green region comprises a first central nanopost offset from a center of the first green region by a first longitudinal shift on a Y-axis direction and a first horizontal shift on a X-axis direction of the first central nanopost from a top view,
wherein the second green region comprises a second central nanopost offset from a center of the second green region by a second longitudinal shift on the Y-axis direction and a second horizontal shift on the X-axis direction of the second central nanopost from the top view.

2. The image device of claim 1, wherein the first longitudinal shift and the first horizontal shift are determined according to an incidence angle and an azimuthal angle of the first green region,
wherein the incidence angle of the first green region is between a first incident light on an upper surface of the first green region and a normal line of the upper surface of the first green region, and
wherein the azimuthal angle of the first green region is between a horizontal axis of the metasurface layer that passes through a center of the metasurface layer and a first connection line between the center of the first green region and the center of the metasurface layer.

3. The image device of claim 2, wherein the metasurface layer further comprises a second pixel unit, wherein the second pixel unit comprises a third green region, the third green region comprises a third central nanopost offset from a center of the third green region by a third longitudinal shift on the Y-axis direction and a third horizontal shift on the X-axis direction of the third central nanopost from the top view, wherein the third longitudinal shift and the third horizontal shift are determined according to an incidence angle and an azimuthal angle of the third green region,
wherein the incidence angle of the third green region is between a second incident light on an upper surface of the third green region and a normal line of the upper surface of the third green region,
wherein the azimuthal angle of the third green region is between the horizontal axis of the metasurface layer that passes through the center of the metasurface layer and a second connection line between the center of the third green region and the center of the metasurface layer, and wherein the first longitudinal shift of the first central nanopost and the third longitudinal shift of the third central nanopost satisfy the following equation:
$${D}_{GR} ( θ , ∅ ) = {D}_{GR} ( {θ}_{i} , {∅}_{j} ) + Δθ \frac{\partial {D}_{GR}}{\partial θ} + Δ∅ \frac{\partial {D}_{GR}}{\partial ∅}$$
wherein θ is the incidence angle of the first green region and θ is not equal to 0 degrees, Ø is the azimuthal angle of the first green region, D_{GR}(θ,Ø) is the first longitudinal shift of the first central nanopost, θᵢ is the incidence angle of the third green region and θᵢ is not equal to 0 degrees, Øⱼ is the azimuthal angle of the third green region, D_{GR}(θᵢ, Øⱼ) is the third longitudinal shift of the third central nanopost, Δθ is a first difference between the incidence angle of the first green region and the incidence angle of the third green region, ΔØ is a second difference between the azimuthal angle of the first green region and the azimuthal angle of the third green region.

4. The image device of claim 3, wherein the first horizontal shift of the first central nanopost and the third horizontal shift of the third central nanopost satisfy the following equation:
$${D}_{GB} ( θ , ∅ ) = {D}_{GB} ( {θ}_{i} , {∅}_{j} ) + Δθ \frac{\partial {D}_{GB}}{\partial θ} + Δ∅ \frac{\partial {D}_{GB}}{\partial ∅}$$
wherein D_{GB}(θ,Ø) is the first horizontal shift of the first central nanopost, and D_{GB}(θᵢ,Øⱼ) is the third horizontal shift of the third central nanopost.

5. The image device of claim 4, wherein an edge of the first green region is offset from a corresponding edge of the first green filter by an offset distance of the first green region, the color filter layer comprises a third green filter adjacent to the first green filter, the third green region is above the third green filter, and an edge of the third green region is offset from a corresponding edge of the third green filter by an offset distance of the third green region, and
wherein the offset distance of the first green region and the offset distance of the third green region satisfy the following equation:
$$S ( θ ) = S ( {θ}_{i} ) + Δθ \frac{dS}{d θ}$$
wherein S(θ) is the offset distance of the first green region, and S(θᵢ) is the offset distance of the third green region.

6. The image device of claim 5, wherein the offset distance of the first green region is in a range from 0 to 300 nm, θ is greater than 0 degrees and ≤35 degrees, and Ø is in a range from 0 to 360 degrees.

7. The image device of claim 1, wherein the metasurface layer further comprises a plurality of peripheral nanoposts, and the peripheral nanoposts are located at corners of the blue region, the red region, the first green region, and the second green region.

8. The image device of claim 1, wherein the first longitudinal shift of the first central nanopost is within ⅕ of a dimension of the first green filter, and the first horizontal shift of the first central nanopost is within ⅕ of the dimension of the first green filter.

9. The image device of claim 1, wherein the first longitudinal shift and the first horizontal shift comprises positive shifts,
wherein the second longitudinal shift and the second horizontal shift comprises positive shifts,
wherein the positive shift of the first longitudinal shift is defined by a shift from the first green region toward the red region, and the positive shift of the first horizontal shift is defined by a shift from the first green region toward the blue region,
wherein the positive shift of the second longitudinal shift is defined by a shift from the second green region toward the blue region, and the positive shift of the second horizontal shift is defined by a shift from the second green region toward the red region.

10. The image device of claim 1, wherein the first longitudinal shift and the first horizontal shift comprise negative shifts,
wherein the second longitudinal shift and the second horizontal shift comprise negative shifts,
wherein the negative shift of the first longitudinal shift is defined by a shift from the first green region away from the red region, and the negative shift of the first horizontal shift is defined by a shift from the first green region away from the blue region,
wherein the negative shift of the second longitudinal shift is defined by a shift from the second green region away from the blue region, and the negative shift of the second horizontal shift is defined by a shift from the second green region away from the red region.

11. The image device of claim 1, wherein the metasurface layer further comprises a filling material, the filling material laterally encloses the first central nanopost and the second central nanopost, wherein a refractive index of the filling material is in a range from 1.0 to 1.6.

12. The image device of claim 1, wherein the image device further comprises a dielectric layer, the dielectric layer is disposed between the color filter layer and the blue filter, the red filter, the first green filter, and the second green filter.

13. The image device of claim 1, wherein a dimension of each of the blue region, the red region, the first green region, and the second green region is in a range from 400 nm to 700 nm, and
wherein a refractive index of the first central nanopost is in a range from 1.8 to 3.5.

14. A method of forming an image device, comprising:
providing a plurality of photodiodes;
forming a color filter layer over the plurality of photodiodes, wherein the color filter layer comprises a blue filter, a red filter, a first green filter, and a second green filter; and
forming a metasurface layer over the color filter layer, wherein the metasurface layer comprises a first pixel unit, wherein the first pixel unit comprises a blue region above the blue filter, a red region above the red filter, a first green region above the first green filter, and a second green region above the second green filter, wherein the first green region comprises a first central nanopost, the second green region comprises a second central nanopost, and forming the metasurface layer comprises:
forming the first central nanopost offset from a center of the first green region by a first longitudinal shift on a Y-axis direction and a first horizontal shift on a X-axis direction of the first central nanopost from a top view; and
forming the second central nanopost offset from a center of the second green region by a second longitudinal shift on the Y-axis direction and a second horizontal shift on the X-axis direction of the second central nanopost from the top view.

15. The method of forming the image device of claim 14, wherein the first longitudinal shift and the first horizontal shift are determined according to an incidence angle and an azimuthal angle of the first green region,
wherein the incidence angle of the first green region is between a first incident light on an upper surface of the first green region and a normal line of the upper surface of the first green region, and
wherein the azimuthal angle of the first green region is between a horizontal axis of the metasurface layer that passes through a center of the metasurface layer and a first connection line between the center of the first green region and the center of the metasurface layer.

16. The method of forming the image device of claim 14, wherein forming the metasurface layer further comprises forming a plurality of peripheral nanoposts at corners of the blue region, the red region, the first green region, and the second green region.

17. The method of forming the image device of claim 16, wherein forming the metasurface layer further comprises forming a filling material laterally enclosing the peripheral nanoposts, the first central nanopost, and the second central nanopost.

18. The method of forming the image device of claim 14, further comprises forming a dielectric layer disposed between the color filter layer and the blue filter, the red filter, the first green filter, and the second green filter.

19. The method of forming the image device of claim 14, wherein the first longitudinal shift and the first horizontal shift comprise positive shifts,
wherein the second longitudinal shift and the second horizontal shift comprises positive shifts,
wherein the positive shift of the first longitudinal shift is defined by a shift from the first green region toward the red region, and the positive shift of the first horizontal shift is defined by a shift from the first green region toward the blue region,
wherein the positive shift of the second longitudinal shift is defined by a shift from the second green region toward the blue region, and the positive shift of the second horizontal shift is defined by a shift from the second green region toward the red region.

20. The method of forming the image device of claim 14, wherein the first longitudinal shift and the first horizontal shift comprise negative shifts,
wherein the second longitudinal shift and the second horizontal shift comprise negative shifts,
wherein the negative shift of the first longitudinal shift is defined by a shift from the first green region away from the red region, and the negative shift of the first horizontal shift is defined by a shift from the first green region away from the blue region,
wherein the negative shift of the second longitudinal shift is defined by a shift from the second green region away from the blue region, and the negative shift of the second horizontal shift is defined by a shift from the second green region away from the red region.
